(19) United States
(12) Patent Application Publication
(10) Pub. No.: US 2006/0157745 A1
(43) Pub. Date: Jul. 20, 2006

(54) Vertical unipolar component with a low leakage current

(75) Inventor: Frederic Lanois, Tours (FR)

Correspondence Address: STMicroelectronics Inc.;c/o WOLF, GREENFIELD & SACKS, PC, Federal Reserve Plaza, 600 Atlantic Avenue, BOSTON, MA, 02210-2206, US

(73) Assignee: STMicroelectronics S.A., Montrouge (FR)

(21) Appl. No.: 11/333,471

(22) Filed: Jan. 17, 2006

(30) Foreign Application Priority Data
Jan. 18, 2005 (FR) 05/50141

(51) Int. Cl. H01L 29/80

(52) U.S. Cl. 257/256

(57) ABSTRACT

A TMBS-type Schottky diode including main electrodes on active areas on the upper surface side and a main electrode on the lower surface side, including on the upper surface side conductive fingers penetrating between the active areas and biased, directly or indirectly, like the active areas. The fingers includes closer portions on their upper portion side than on their bottom side. The fingers preferably are polysilicon fingers insulated by an insulating layer such as silicon oxide.

### BACKGROUND OF THE INVENTION

1. Field of the Invention

The present invention relates to vertical unipolar components.

2. Discussion of the Related Art The following description more specifically aims, as an example only, at the case of components of Schottky diode type made in vertical form in silicon substrates. However, the present invention also applies to any vertical unipolar structure and to the monolithic forming thereof in a semiconductor substrate.

Conventionally, a Schottky diode includes a heavily-doped semiconductor substrate, typically made of single-crystal silicon. A cathode layer more lightly doped than the substrate covers the substrate. A metal layer or more currently a metal silicide forms a Schottky contact with the cathode and forms the diode anode.

The forming of such unipolar components faces two opposite constraints. Said components must exhibit the lowest possible on-state resistance (Ron) while having a high breakdown voltage. Minimizing the on-state resistance imposes minimizing the thickness of the less doped layer and maximizing the doping of this layer. Conversely, to obtain a high reverse breakdown voltage, the doping of the less doped layer must be minimized and its thickness must be maximized, while avoiding creation of areas in which the equipotential surfaces are strongly bent.

Various solutions have been provided to reconcile these opposite constraints, which has led to the obtaining of MOS-capacitance Schottky diode structures, currently designated as TMBS, for Trench MOS Barrier Schottky. In an example of such structures, conductive areas, for example, heavily-doped N-type polysilicon areas, are formed in an upper portion of a thick cathode layer less heavily N-type doped than an underlying substrate. An insulating layer insulates the conductive areas from the thick layer. An anode layer covers the entire structure, contacting the upper surface of the insulated conductive areas and forming a Schottky contact with the cathode.

In reverse biasing, the insulated conductive areas cause a lateral depletion of the cathode layer, which modifies the distribution of the equipotential surfaces in this layer. This enables increasing the cathode layer doping, and thus reducing the on-state resistance with no adverse effect on the reverse breakdown voltage.

FIG. 1 is a partial view of examples of prior art TMBS Schottky diodes. The diode is formed from a heavily-doped N-type silicon wafer 1 on which is formed a lightly-doped N-type epitaxial layer 2. In this epitaxial layer, in the area corresponding to the actual component, are formed openings, for example, trench-shaped. In these openings are formed conductive fingers 3, for example, made of polysilicon doped to be conductive, an insulating layer 4 being interposed between each conductive finger and the walls of the corresponding opening. Insulating layer 4 for example results from a thermal oxidation and the filling with polysilicon may be performed by conformal deposition, this filling step being followed by a planarization step. After this, a metal, for example, nickel, capable of forming a silicide 5 above the single-crystal silicon regions and 6 above the polysilicon filling areas, is deposited. Once the silicide has been formed, the metal which has not reacted with the silicon is removed by selective etch. After this, an anode metal deposition 7 is formed on the upper surface side and a cathode metal deposition 8 is formed on the lower surface side.

As compared with a trenchless Schottky diode, the TMBS structure of FIG. 1 well improves, as desired, the forward voltage drop for a desired reverse breakdown voltage.

However, in this structure, the reduction of the reverse leakage current poses a problem. Indeed, the designer can select a number of parameters but some of these are set by the first performed selections. Generally, the first parameter which is set is the reverse breakdown voltage. If a reverse breakdown voltage of 120 volts at 25° C. is for example desired, various values may be selected for the doping level of N-type layer 2, it being understood that a higher doping level will favor a lower forward voltage drop. For example, table 1 hereafter provides examples of structures A and B both having a 120-V reverse breakdown voltage and exhibiting, one a doping level on the order of 5.10¹⁵ atoms/cm³, the other a doping level on the order of 1.3.10¹⁶ atoms/cm³ for epitaxial layer 2.

TABLE 1

| Structure | VBR(V) | N(at/cm3) | W(μm) | VF(v) | IR(mA) |
|---|---|---|---|---|---|
| A | 120 | 5.10¹⁵ | 7 | 0.58 | 6.2 |
| B | 120 | 1.3.10¹⁶ | 5.5 | 0.46 | 51 |

In table 1, VBR designates the breakdown voltage expressed in volts, N the doping deposition level of the epitaxial layer in atoms per cm³, W the thickness of the epitaxial layer in micrometers, VF the forward voltage drop at 125° C. in volts, and IR the reverse leakage current at 125° C. in milliamperes. It can be seen that an increase in the doping level and a decrease in the thickness of the epitaxial layer cause a significant reduction in the forward voltage drop which falls from 0.58 to 0.46 volt. However, the reverse leakage current clearly increases, and switches from 6.2 mA to 51 mA. This is due to the fact that, when the doping level of the epitaxial layer increases, the field at the level of the Schottky barrier (or Schottky junction) increases, which inevitably causes an increase in the leakage current

### SUMMARY OF THE INVENTION

The present invention aims at providing a novel TMBS-type component exhibiting both a small forward voltage drop and a low reverse leakage current.

To achieve this and other objects, the present invention provides a vertical unipolar component comprising main electrodes on active areas on the upper surface side and a main electrode on the lower surface side, comprising on the upper surface side conductive fingers penetrating between the active areas and biased, directly or indirectly, like the active areas. The fingers comprise closer portions on their upper portion side than on their bottom side.

According to an embodiment of the present invention, the vertical unipolar component forms a TMBS-type Schottky diode and the fingers are polysilicon fingers insulated by an insulating layer such as silicon oxide, the fingers comprising an upper portion which is wider than their lower portion.

According to an embodiment of the present invention, deep parallel fingers are surrounded with shallower parallel fingers, closer to one another.

According to an embodiment of the present invention, deep parallel fingers are crossed by shallower parallel fingers closer to one another.

The present invention also aims at a method for manufacturing a TMBS Schottky diode, comprising the steps of forming in the upper layer of the component polysilicon fingers surrounded with silicon oxide; partially etching the silicon oxide layer surrounding the upper portion of the fingers; performing a thermal oxidation; and filling with polysilicon the remaining hollow portions.

The foregoing and other objects, features, and advantages of the present invention will be discussed in detail in the following non-limiting description of specific embodiments in connection with the accompanying drawings.

### BRIEF DESCRIPTION OF THE DRAWINGS

FIG. 1 is a partial cross-section view of the active portion of a TMBS component of prior art;

FIG. 2 is a partial simplified cross-section view of the active portion of a TMBS component according to an embodiment of the present invention;

FIGS. 3A and 3B respectively are a cross-section view and a top view of the active portion of a TMBS component according to an embodiment of the present invention;

FIGS. 4A, 4B, and 4C respectively are two cross-section views and a top view of the active portion of a TMBS component according to an embodiment of the present invention;

FIGS. 5A, 5B, 5C are cross-section views of successive steps of a specific method for forming a TMBS component according to an embodiment of the present invention; and

FIG. 5D is a top view corresponding to the cross-section view of FIG. 5C.

### DETAILED DESCRIPTION

For clarity, the same elements have been designated with the same reference numerals in the different drawings and, further, as usual in the representation of integrated circuits, the various drawings are not to scale.

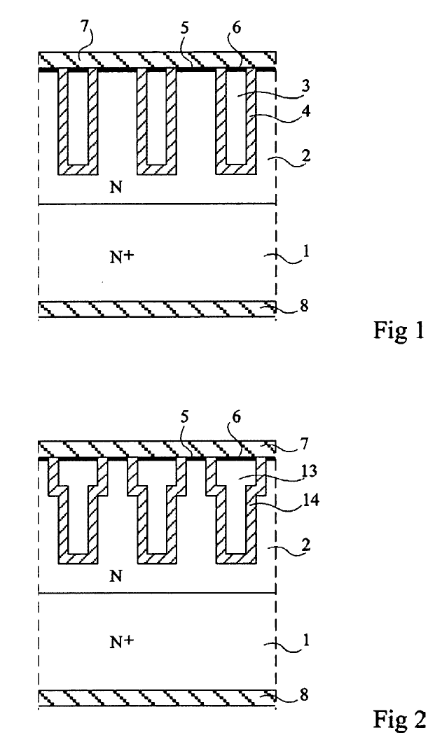

FIG. 2 illustrates an embodiment of the present invention. It shows substrate 1, epitaxial layer 2, Schottky contacts 5 on the upper surface of epitaxial layer 2, the corresponding metallization 6 on polysilicon areas, upper electrode 7 and lower electrode 8 already described in relation with FIG. 1. The conductive fingers, for example, made of polysilicon, are designated with reference numeral 13 and their insulation is designated as 14. According to the present invention, as shown in FIG. 1, conductive fingers 13 are closer in their upper portions than in their lower portions. Thus, when a reverse voltage is applied, the pinch occurs for a smaller voltage in the upper portion of the epitaxial layer 2 located between the fingers than in the lower portion of this epitaxial layer located between the fingers. This results, when the diode is reverse-biased, in more depletion of the portion of epitaxial layer 2 located between the conductive fingers at the level of the upper surface, and thus in a reduction of the field at the level of the upper surface and a reduction in the reverse leakage current.

The embodiment of the present invention illustrated in FIG. 2, in which the conductor ensuring the pinch of the areas of the epitaxial layers between them is larger at the top than at the bottom, is likely to have various alternative embodiments. For example, the trenches may be V-shaped, the tip of the V being directed downwards.

Other embodiments will be described in relation with the following drawings, as an example only.

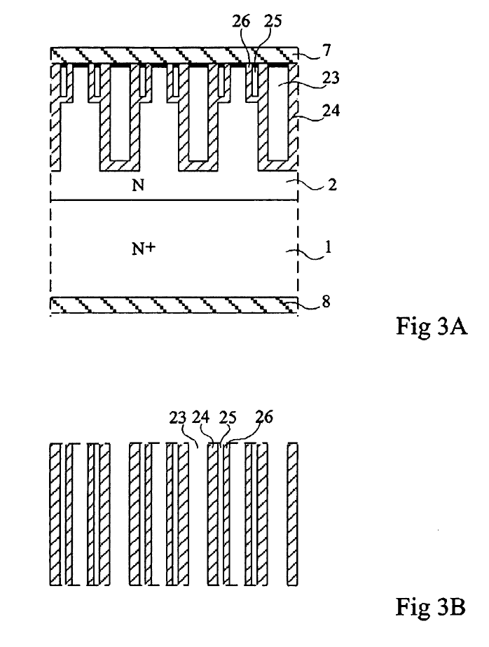

An embodiment of the present invention is shown in cross-section view in FIG. 3A and in top view in FIG. 3B. The conductive fingers are formed in trenches comprising main trenches surrounded with shallower lateral trenches. The main trenches contain conductive fingers 23 insulated by an oxide 24. The lateral trenches contain conductive fingers 25 insulated by an oxide 26. Oxide 26 may have a smaller thickness than oxide 24, which enables depletion of the region located under the silicide. Fingers 23 and 25 are in contact with the anode layer, possibly via the Schottky metal which has deposited thereon in the manufacturing process. As illustrated by the top view of FIG. 3B, the trenches have the shape of parallel strips.

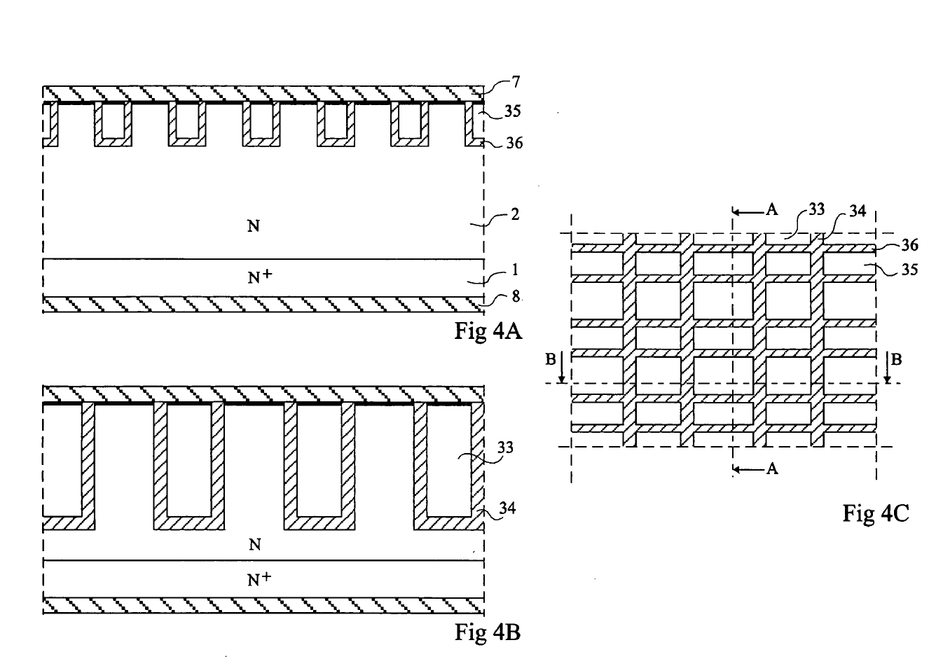

FIGS. 4A to 4C illustrate another embodiment of the present invention, FIGS. 4A to 4B being cross-section views, respectively along planes A-A and B-B of FIG. 4C. In this embodiment, a first series of deeper and more distant trenches containing conductive fingers 33 surrounded with an insulator 34 and a second series of shallower and closer trenches 35 containing conductive fingers 35 surrounded with an insulator 36 are provided. These two sets of trenches are, for example, perpendicular, as shown in the top view of FIG. 4C. It should be understood that the closer trenches ensure a greater depletion in the surface area of the component. Insulator 36 may have a smaller thickness than insulator 34, which enables depletion of the region located under the silicide and a significant reduction of the field under the silicide.

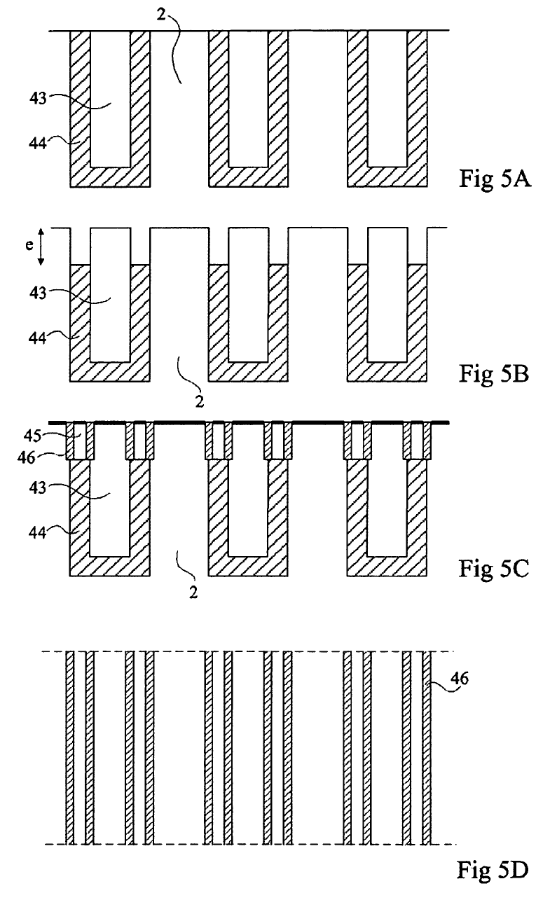

FIGS. 5A to 5C are cross-section views illustrating an example of a manufacturing method of another embodiment of the present invention.

As illustrated in FIG. 5A, deep trenches containing conductive fingers 43 surrounded with an insulator 44 are first formed. For this purpose, trenches of the desired shape are formed (strip-shaped or round or square openings) after which a thermal oxidation is carried out to form insulator 44, after which the trench is filled with a conductor, for example, heavily-doped polysilicon.

In a next step, illustrated in FIG. 5B, a silicon oxide 44 is selectively etched down to a limited depth e.

After this, as illustrated in FIG. 5C, a new thermal oxidation is performed to form insulating areas 46 above the lateral upper portion of the trenches hollowed down to depth e and the partial trenches thus formed are filled with a conductor 45, again preferably doped polysilicon.

After this, the usual steps of the forming of a TMBS-type component are carried out.

Table 2 compares the features of a TMBS structure according to prior art (C) with those of a structure of the type shown in FIG. 5 (D), with the same notations as those used for table 1. The strong decrease in the reverse leakage current should be noted.

TABLE 2

| Structure | VBR(V) | N(at/cm3) | W(μm) | VF(v) | IR(mA) |
|---|---|---|---|---|---|
| C | 120 | 1.2.10¹⁶ | 6 | 0.47 | 33 |
| D | 120 | 1.2.10¹⁶ | 6 | 0.47 | 10 |

The present invention is likely to have various variations adapted to the various types of Schottky-barrier components. For example, in some embodiments, the Schottky barrier component, instead of comprising laterally-insulated trenches, may comprise P-type regions properly doped with respect to the epitaxial layer. Such P-type regions will have according to the present invention an upper portion which is wider than their lower portion. Similarly, embodiments in which P-type regions or insulated conductive regions spaced apart from one another in depth are formed, are know. In the two latter cases, the P-type regions or the insulated conductive regions may be individually biased by capacitive effect. Again, according to the present invention, the upper regions will comprise portions closer than the lower regions.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A vertical unipolar component comprising main electrodes on active areas on an upper surface side and a main electrode on the lower surface side, comprising on the upper surface side conductive fingers penetrating between the active areas and biased, directly or indirectly, like the active areas, wherein said fingers comprise closer portions on their upper portion side than on their bottom side.

2. The vertical unipolar component of claim 1, forming a TMBS-type Schottky diode wherein the fingers are polysilicon fingers insulated by an insulating layer such as silicon oxide, the fingers comprising an upper portion which is wider than their lower portion.

3. The vertical unipolar component of claim 2, wherein deep parallel fingers are surrounded with shallower parallel fingers, closer to one another.

4. The vertical unipolar component of claim 2, wherein deep parallel fingers are crossed by shallower parallel fingers closer to one another.

5. A method for manufacturing a TMBS Schottky diode, comprising the steps of:
forming in the upper layer of the component polysilicon fingers surrounded with silicon oxide;
partially etching the silicon oxide layer surrounding the upper portion of the fingers;
performing a thermal oxidation; and
filling with polysilicon the remaining hollow portions.
